(19) United States
(12) Patent Application Publication
(10) Pub. No.: US 2013/0175554 A1
(43) Pub. Date: Jul. 11, 2013

(54) LED PACKAGE SUBSTRATE AND METHOD OF MANUFACTURING LED PACKAGE

(71) Applicant: Samsung Electronics Co., Ltd., Suwon-si (KR)

(72) Inventors: Sang Ho HAN, Incheon (KR); Jin Ha KIM, Seoul (KR); Chin Woo KIM, Suwon (KR); Sung Ho JEON, Seoul (KR); Seok Man CHO, Seoul (KR)

(73) Assignee: SAMSUNG ELECTRONICS CO., LTD., Suwon-si (KR)

(21) Appl. No.: 13/737,280

(22) Filed: Jan. 9, 2013

(30) Foreign Application Priority Data
Jan. 9, 2012 (KR) 10-2012-0002534

(51) Int. Cl. H01L 33/48

(52) U.S. Cl. CPC H01L 33/48
USPC 257/88; 438/28

(57) ABSTRACT

There is provided a light emitting diode (LED) package substrate including: a substrate including a chip mounting region on which a plurality of LED chips is mountable; a conductive layer including a plurality of electrode patterns disposed on the chip mounting region; and a groove part, forming a dam, wherein the groove part surrounds the chip mounting region and is spaced apart from the chip mounting region by a predetermined interval.

### CROSS-REFERENCE TO RELATED APPLICATION

This application claims the priority of Korean Patent Application No. 10-2012-0002534 filed on Jan. 9, 2012, in the Korean Intellectual Property Office, the disclosure of which is incorporated herein by reference.

### BACKGROUND

1. Field

Apparatuses and methods consistent with exemplary embodiments relate to an LED package, and more particularly, to an LED package substrate and a method of manufacturing an LED package using the same.

2. Description of the Related Art

A light emitting diode (hereinafter, referred to as an “LED”) is a semiconductor device converting electrical energy into optical energy and configured of a compound semiconductor emitting light of a particular wavelength, according to an energy band gap. LEDs have come into widespread use in back light units (BLUs) for display devices such as optical communications or mobile display devices, computer monitors, or the like, for liquid crystal displays (LCDs), and in general illumination devices.

In the related art, an LED package has mainly been manufactured by encasing an LED chip with a liquid crystal resin containing phosphor to emit white light through a well-known method such as a dispensing method or the like. In this case, there may be a defect in which, since amounts of phosphors positioned above an upper surface and beside a side surface of an LED chip may be different, a difference in color properties such as a color temperature between white light emitted from a chip's upper surface and white light emitted from a chip's side surface may occur. In particular, when a resin layer is simultaneously applied to a plurality of LED chips for the mass production thereof, a distribution defect occurring in an individual chip may be large, and in addition, there has been inconvenience in which a separate dam should be installed in order to define a resin layer application region.

### SUMMARY

One or more exemplary embodiments may provide an LED package manufacturing technology capable of simplifying a resin packaging process by simultaneously applying layers of various forms of resin, such as a phosphor-containing resin layer, to a plurality of LED packages.

According to an aspect of an exemplary embodiment, there is provided a light emitting diode (LED) package substrate including: a substrate including a chip mounting region on which a plurality of LED chips is mountable; a conductive layer including a plurality of electrode patterns formed disposed on the chip mounting region; and a groove part, forming a dam, wherein the groove part surrounds the chip mounting region and is spaced apart from the chip mounting region by a predetermined interval.

The conductive layer may further include a surplus conductive region disposed on the substrate and surrounding the chip mounting region. In this case, the surplus conductive region may be divided into an inner conductive region surrounding the chip mounting region and an outer conductive region surrounding the inner conductive region. A depth of the groove part may be deeper than a thickness of the conductive layer. The substrate may be a ceramic substrate.

According to an aspect of another exemplary embodiment, there is provided a method of manufacturing an LED package, including: providing an LED package substrate including a substrate having a chip mounting region, a conductive layer including a plurality of electrode patterns formed on the chip mounting region, and a groove part, forming a dam, wherein the groove part surrounds the chip mounting region and is spaced from the chip mounting region by a predetermined interval; mounting the plurality of respective LED chips on the chip mounting region and connecting each of the plurality of LED chips to one of the plurality of electrode patterns; applying a liquid resin such that the liquid resin surrounds the plurality of LED chips mounted on the chip mounting region, wherein a region of the LED package substrate covered with the liquid resin is defined by the groove part; curing the liquid resin; and cutting the substrate into individual LED package units.

The conductive layer may further include a surplus conductive region disposed on the substrate and surrounding the chip mounting region. In this case, the surplus conductive region may be divided into an inner conductive region surrounding the chip mounting region and an outer conductive region surrounding the inner conductive region.

The cutting of the substrate into the individual LED package units may include separating the chip mounting region from the surplus conductive region and the substrate having the surplus conductive region formed thereon.

The liquid resin may be a transparent resin containing a phosphor.

The applying of the liquid resin may include applying a first liquid resin to surround at least portions of lateral surfaces of the LED chips, and applying a second liquid resin to cover the LED chips to which the first liquid resin has been applied. In this case, the first liquid resin may be a transparent resin containing a photo-reflective powder, and the second liquid resin may be a transparent resin containing a phosphor.

### BRIEF DESCRIPTION OF THE DRAWINGS

The above and/or other exemplary aspects, features and advantages will be more clearly understood from the following detailed description of exemplary embodiments taken in conjunction with the accompanying drawings, in which:

FIG. 1 is a side cross-sectional view of an LED package substrate in a state in which LED chips are mounted according to an exemplary embodiment;

FIGS. 2A and 2B are a top plan view and a side cross-sectional view illustrating an LED package substrate according to another exemplary embodiment;

FIGS. 3 to 5 are side cross-sectional views illustrating main processes for explaining an example of a method of manufacturing an LED package by using an LED package substrate shown in FIGS. 2A and 2B; and

FIG. 6 is a side cross-sectional view of an LED package manufactured according to a manufacturing method illustrated in FIGS. 3 to 5.

### DETAILED DESCRIPTION OF THE EMBODIMENTS

Exemplary embodiments will now be described in detail with reference to the accompanying drawings, such that those having ordinary skill in the art to which the invention pertains could easily implement the embodiments described herein. However, it should be noted that the embodiments as set forth herein are not to be considered as limiting and that those of skill in the art could easily accomplish retrogressive inventions or other embodiments included in the spirit of the presented exemplary embodiments by the addition, modification, and removal of components within the same spirit, and those are to be construed as being included in the spirit of the inventive concept.

In addition, like or similar reference numerals denote parts performing similar functions and actions throughout the drawings.

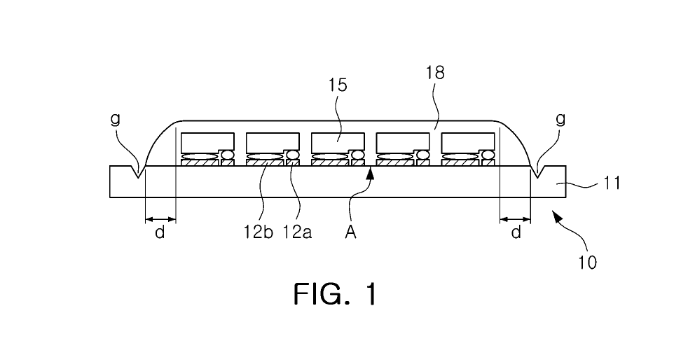

FIG. 1 is a side cross-sectional view of an LED package substrate in a state in which LED chips are mounted according to an exemplary embodiment.

An LED package substrate 10 according to an exemplary embodiment may include a substrate 11 having a chip mounting region A, allowing for a plurality of LED chips 15 to be mounted thereon, and a conductive layer formed on the substrate 11.

The conductive layer may include a plurality of electrode patterns 12a and 12b disposed on the chip mounting region A and connected to the plurality of respective LED chips 15. In the present embodiment, the LED chips 15 are illustrated as having a flip-chip structure, but this should not be considered to be limiting, and the LED chips may alternately have an epi-up structure in which they are formed to be directed upwardly, and/or one or more LED chips connected to at least one of the electrode patterns 12a and 12b through one or more wires may be used.

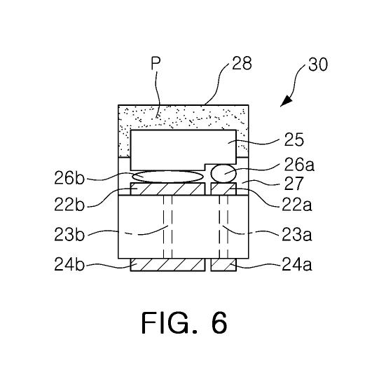

The substrate 11 may be a ceramic substrate, and although not shown in FIG. 1, the substrate 11 may include conductive vias formed to penetrate therethrough while being respectively connected to electrode patterns 12a and 12b, and external terminals formed on a lower surface of the substrate to be respectively connected to the conductive vias (please refer to FIG. 6).

The package substrate 10 may include a groove part g, forming a dam, formed to surround the chip mounting region A, on the substrate 11. The groove part g, forming a dam, may define a region within which a liquid resin 18 for forming a resin packaging part of the LED package is applied.

That is, the surface of the substrate 11 is divided by using the groove part g, forming a dam, and thus, a flow of the liquid resin 18 applied to the LED chip 15 is retained within the cut-off portion due to surface tension, and by using the operation described above, the region to which the liquid resin 18 is applied may be limited to a region surrounded by the groove part g.

In the present embodiment, a plurality of LED packages may be mounted on the chip mounting region A of the package substrate 10. A liquid resin of the LED chips 15 applied to an inner portion of the chip mounting region A may have an appropriate viscosity, and a resin packaging part having a comparatively uniform thickness and a predetermined shape may be obtained through an array interval between arrayed LED chips therein, while since a resin packaging part formed around the chip mounting region A has an inclined surface extended out to the groove part g, a resin packaging part having a different form from that provided to the LED chips positioned in the inner region of the chip mounting region may be provided.

In order to relieve the defect described above, the groove part g, forming a dam employed in the present embodiment may be spaced apart from the LED chips by a predetermined interval d as shown in FIG. 1. An outermost LED chip 15 may also provide a resin packaging part having a relatively uniform thickness and a predetermined shape by presetting the interval d in consideration of an inclined portion of the resin located in an edge of the resin packaging part.

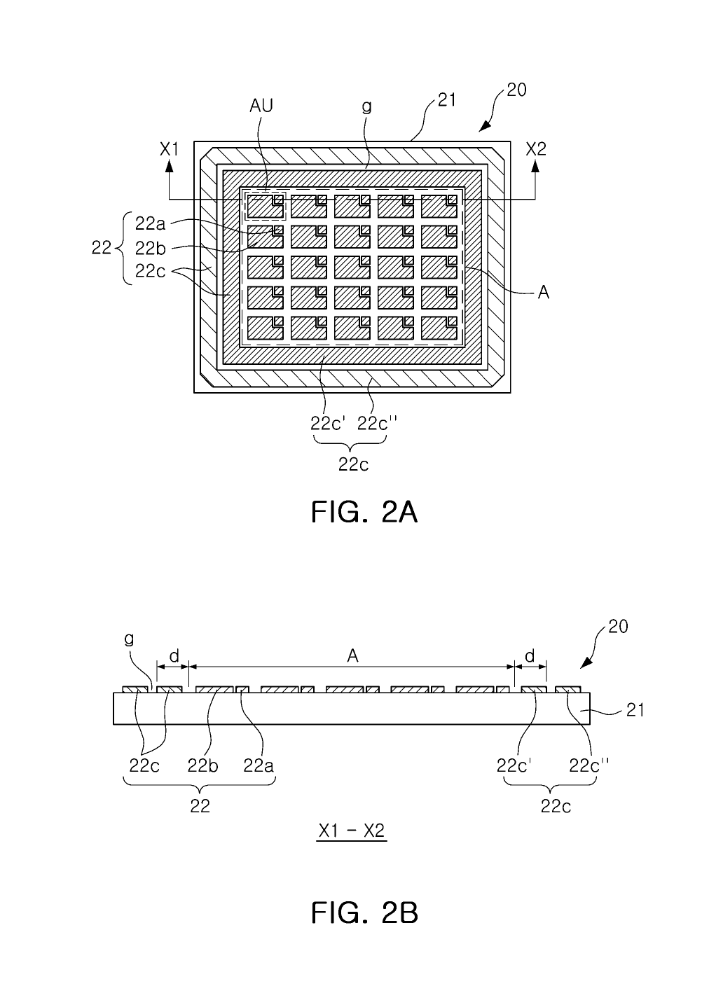

Although the groove part, forming the dam (g of FIG. 1) employed in this embodiment is illustrated in a state in which the groove part is directly processed in a surface of the substrate, this is not limiting, and the groove may have varied and diverse forms. For example, in order to form an electrode pattern, a groove part, forming a dam may be formed by using a margin of a conductive layer for an electrode pattern on a substrate's upper surface. An embodiment thereof is illustrated in FIGS. 2A and 2B.

With reference to FIGS. 2A and 2B, the LED package substrate 20 according to this exemplary embodiment may include a substrate 21 having a chip mounting region A for a plurality of LED chips, and a conductive layer 22 formed on the substrate 21.

The conductive layer 22 according to this embodiment may include a surplus conductive region 22c surrounding the plurality of electrode patterns 22a and 22b and the chip mounting region. In a similar manner to the previously described embodiment, the electrode patterns 22a and 22b may be formed in positions corresponding to the plurality of LED chips to be mounted on the chip mounting region A. In the surplus conductive region 22c, a groove part g, forming a dam may be formed to surround the chip mounting region A.

The surplus conductive region 22c may be divided into an inner conductive region 22c′ and an outer conductive region 22c″, based on the groove part g, forming the dam. As shown in FIG. 2B, since a depth of the groove part g, forming the dam, may be obtained by patterning the conductive layer 22, the depth thereof may pertain to a thickness of the conductive layer 22. However, this should not be considered to be limiting, and the groove part g may have a depth deeper than the thickness of the conductive layer 22 by additionally processing the substrate 21. In order to allow the groove part g to serve as a boundary of a region in which a resin packaging part is formed by using a surface tension, the groove part g may be formed to have a depth of 100 μm or more.

The groove part g according to the present embodiment may be formed during a patterning process of the conductive layer 22 in which the electrode patterns 22a and 22b are formed. Therefore, since the groove part g may be obtained without performing a separate dam forming process, the process thereof may be simplified.

The groove part g, forming the dam, employed in the present embodiment, may be spaced apart from the chip mounting region by a predetermined interval d, as shown in FIGS. 2A and 2B. As such, by setting the interval d in advance in consideration of the inclined portion positioned on an edge of the resin packaging part, a resin packaging part in which the LED chip 15 positioned on the edge thereof also has a comparatively uniform thickness and a predetermined shape may be achieved.

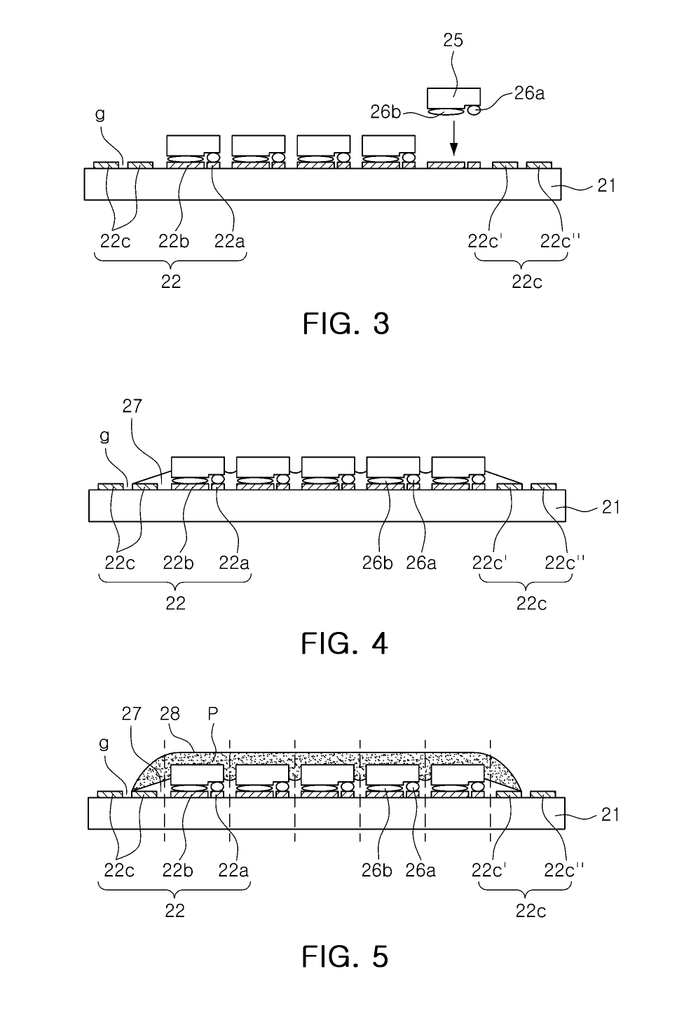

FIGS. 3 to 5 are side cross-sectional views illustrating an exemplary method of manufacturing an LED package by using an LED package substrate shown in FIGS. 2A and 2B.

First, as shown in FIG. 3, the plurality of respective LED chips 25 may be mounted on the chip mounting region A to be connected to the plurality of electrode patterns 22a and 22b.

In the present embodiment, the LED chips 25 are illustrated as having a flip-chip structure, but this should not be considered to be limiting, and the LED chips may have an epi-up structure in which they are formed to be directed upwardly, and/or one or more LED chips connected to at least one of the electrode patterns 22a and 22b through one or more wires may be used.

Subsequently, a liquid resin may be applied to surround the plurality of LED chips mounted on the chip mounting region. In that case, the region covered with the liquid resin may be defined by the groove part g, forming the dam. This process using a liquid resin may be implemented through a well-known process such as a dispensing process.

The process described above, using a liquid resin, may be performed in two or more operations, forming two or more layers in order to obtain different functions as shown in FIGS. 4 and 5.

First, as shown in FIG. 4, a first liquid resin 27 may be applied to surround at least portions of lateral surfaces of the LED chips 25 and may be cured.

The first liquid resin 27 used in the present process is a generally used packaging material and may be a transparent resin such as a silicon, an epoxy, or a mixer thereof. The first liquid resin 27 may fill a space between the plurality of LED chips 25 and may include a photo-reflective powder. As the photo-reflective powder (not shown), a white insulating powder such as a titanium oxide (TiO2) or Al2O3 may be used. As described above, a formation region of the first liquid resin 27 may be defined by the groove part g, forming a dam. A resin packaging region obtained from the first liquid resin 27 may be formed to have a required height, by supplying an appropriate amount of the first liquid resin 27, using the groove part g, forming the dam.

Next, as shown in FIG. 5, a second liquid resin 28 may be applied so as to cover the LED chips 25 to which the first liquid resin 27 has been applied and the second liquid resin 28 may then be cured to thus obtain a completed resin packaging part.

The second liquid resin 28 may be formed of a general packaging material, that is, a transparent resin such as a silicon, an epoxy, or a mixer thereof, and may be formed of the same transparent resin as that of the first liquid resin 27. The second liquid resin 28 may include a phosphor P for converting a wavelength of light generated from the LED chips 25.

In a similar manner to the process relating to the first liquid resin 27, a formation region of the second liquid resin 28 may be defined by the groove part g, forming the dam. A resin packaging region obtained from the second liquid resin 28 may be formed to have a required height, by supplying an appropriate amount of the second liquid resin 28, using the groove part g, forming the dam.

Subsequently, the LED package substrate 20 may be cut into individual LED package units to include the LED chip 25 therein, along dotted lines of FIG. 5. The LED packages obtained through the process described above are illustrated in FIG. 6.

As shown in FIG. 6, the LED package 30 may include conductive vias 23a and 23b, formed to penetrate the substrate 21 while being respectively connected to the electrode patterns 22a and 22bm, and external terminals 24a and 24b formed on a lower surface of the substrate 21 to be respectively connected to the conductive vias 23a and 23b. Although a structure having the conductive vias and the external terminals as described above is not previously described with reference to FIGS. 2A and 2B, it can be appreciated as a previously formed structure when a substrate such as a ceramic substrate is prepared.

As set forth above, according to one or more exemplary embodiments, a liquid resin applied region for a plurality of LED chips may be easily set by disposing groove parts formed to be spaced apart from a chip mounting region by a predetermined interval on an LED package substrate, and a comparatively uniform form and thickness of a resin layer may be provided to respective LED chips through a simplified process.

While exemplary embodiments have been shown and described, it will be apparent to those skilled in the art that modifications and variations can be made without departing from the spirit and scope of the inventive concept as defined by the appended claims.

What is claimed is:

1. A light emitting diode (LED) package substrate comprising:
a substrate comprising a chip mounting region on which a plurality of LED chips is mountable;
a conductive layer comprising a plurality of electrode patterns disposed on the chip mounting region; and
a groove part, forming a dam, wherein the groove part surrounds the chip mounting region and is spaced apart from the chip mounting region by a predetermined interval.

2. The LED package substrate of claim 1, wherein the conductive layer further comprises a surplus conductive region disposed on the substrate and surrounding the chip mounting region.

3. The LED package substrate of claim 2, wherein the surplus conductive region comprises an inner conductive region, surrounding the chip mounting region, and an outer conductive region, surrounding the inner conductive region, wherein the groove part comprises a space between the inner conductive region and the outer conductive region.

4. The LED package substrate of claim 1, wherein a depth of the groove part is deeper than a thickness of the conductive layer.

5. The LED package substrate of claim 1, wherein the substrate is a ceramic substrate.

6. A method of manufacturing a light emitting diode (LED) package, the method comprising:
providing an LED package substrate comprising:
a substrate comprising a chip mounting region,
a conductive layer comprising a plurality of electrode patterns disposed on the chip mounting region, and
a groove part, forming a dam, wherein the groove part surrounds the chip mounting region and is spaced apart from the chip mounting region by a predetermined interval;
mounting a plurality of LED chips on the chip mounting region, and connecting each of the plurality of LED chips to one of the plurality of electrode patterns;
applying a liquid resin, such that the liquid resin surrounds the plurality of LED chips, wherein a region of the LED package substrate covered with the liquid resin is defined by the groove part;
curing the liquid resin; and
cutting the substrate into individual LED packages.

7. The method of claim 6, wherein the conductive layer further comprises a surplus conductive region disposed on the substrate and surrounding the chip mounting region.

8. The method of claim 7, wherein the surplus conductive region comprises an inner conductive region, surrounding the chip mounting region, and an outer conductive region, surrounding the inner conductive region, wherein the groove part comprises a space between the inner conductive region and the outer conductive region.

9. The method of claim 7, wherein a depth of the groove part is larger than a thickness of the conductive layer.

10. The method of claim 6, wherein the substrate is a ceramic substrate.

11. The method of claim 7, wherein the cutting the substrate into the individual LED packages comprises separating the chip mounting region from a region of the substrate on which the surplus conductive region is formed.

12. The method of claim 6, wherein the liquid resin is transparent and comprises a phosphor.

13. The method of claim 6, wherein the applying the liquid resin comprises applying a first liquid resin to surround at least portions of lateral surfaces of each of the plurality of LED chips, and applying a second liquid resin to entirely cover each of the plurality of LED chips to which the first liquid resin has been applied.

14. The method of claim 13, wherein the first liquid resin is transparent and comprises a photo-reflective powder, and the second liquid resin is transparent and comprises a phosphor.

15. A method of manufacturing a plurality of light emitting diode (LED) packages, the method comprising:
providing a substrate structure comprising:
a substrate,
a conductive layer disposed on the substrate, wherein the conductive layer comprises a plurality of electrode patterns, and
a groove surrounding a chip mounting region of the substrate, wherein the plurality of electrode patterns are disposed within the chip mounting region;
mounting a plurality of LED chips, such that each LED chip is mounted on one of the plurality of electrode patterns;
applying a resin, in a liquid form, to the chip-mounting region, wherein the resin covers each of the plurality of LED chips, and wherein a spreading of the resin beyond the chip mounting region is prevented by the groove;
curing the resin;
dividing the substrate into individual LED packages.

16. The method of claim 15, wherein the groove comprises an indentation cut into the substrate.

17. The method of claim 15, wherein the conductive layer further comprises an inner surplus conductive region surrounding the chip mounting region and an outer surplus conductive region surrounding the inner surplus conductive region.

18. The method of claim 15, wherein the groove comprises a space formed between the inner surplus conductive region and the outer surplus conductive region.

19. The method of claim 18, wherein the groove further comprises an indentation cut into the substrate beneath the space formed between the inner surplus conductive region and the outer surplus conductive region.

20. The method of claim 15, wherein the applying the resin comprises:
applying a first resin, in liquid form, to the chip mounting region, and applying a second resin over the first resin, wherein the first resin comprises a photo-reflective powder, and the second resin comprises a phosphor.
